(19) United States
(12) Patent Application Publication
(10) Pub. No.: US 2011/0228620 A1
(43) Pub. Date: Sep. 22, 2011

(54) TESTING METHOD FOR SEMICONDUCTOR MEMORY DEVICE

(75) Inventor: MIN CHUNG CHOU, HSINCHU CITY (TW)

(73) Assignee: ELITE SEMICONDUCTOR MEMORY TECHNOLOGY INC., HSINCHU (TW)

(21) Appl. No.: 12/728,847

(22) Filed: Mar. 22, 2010

(51) Int. Cl. G11C 29/00

(52) U.S. Cl. 365/201

(57) ABSTRACT

A method comprises simultaneously writing a test bit to a plurality of memory cells in the selected sections of a memory array corresponding to column address signals; individually and successively reading output bits from the memory cells in one of the selected sections of a designated row of the memory array corresponding to column address signals and row address signals; and error-checking the output bits with the test bit, wherein the memory array comprises the plurality of memory cells arranged in rows and columns and the memory cells of each row are divided into a plurality of sections.

### BACKGROUND OF THE INVENTION

1. Field of the Invention

The present invention relates to a method for testing memory cells of a memory device.

2. Description of the Related Art

Semiconductor memory devices are devices in which data can be stored and from which stored data can be retrieved. Semiconductor memory devices can be classified into random access memory (RAM) and read only memory (ROM). RAM is a volatile memory that needs power supply to retain data. ROM is a nonvolatile memory that can retain data even when power is not supplied. Well-known examples of RAM are a dynamic RAM (DRAM) and a static RAM (SRAM). Examples of ROM are a programmable ROM (PROM), an erasable PROM (EPROM), an electrically EPROM (EEPROM), and a flash memory.

A semiconductor memory device comprises a cell array containing a large number of memory cells for storing data. To ensure that a specific memory device functions well, each of the individual memory cells in the device needs to be tested. Specifically, data is written to and read from the memory cells so as to determine whether or not there are defective memory cells in the memory device.

As the density of the memory cells in the memory device increases, the time required to test all the cells also increases. In order to reduce testing time, a data-compression testing mode is used to increase the speed. U.S. Pat. No. 5,913,928 provides a method for testing cells of a memory device.

As shown in FIG. 1, the method comprises a step for testing a predetermined number of cells of the memory array, resulting in each cell having an output bit. Subsequently, output bits are compressed into a compressed bit and the compressed bit is checked for errors. If the error checking step fails, the cells are individually checked for errors to determine which cells are actually defective. However, the method is still time consuming because output bits of the memory cells need to be generated individually.

Accordingly, there is a need to provide a method for rapidly testing the memory cells of a memory device.

### SUMMARY OF THE INVENTION

An aspect of the present invention is to provide a method for testing a memory array of a memory device. The memory array comprises a plurality of memory cells arranged in rows and columns, and the memory cells of each row are divided into a plurality of sections.

According to one embodiment of the present invention, the method comprises simultaneously writing a test bit to the plurality of memory cells in the selected sections of the memory array corresponding to column address signals; individually and successively reading output bits from the memory cells in one of the selected sections of a designated row of the memory array corresponding to the column address signals and row address signals; and error-checking the output bits with the test bit.

Another aspect of the present invention is to provide a method for testing a memory device having a plurality of memory banks, wherein each memory bank comprises a memory array having a plurality of memory cells arranged in rows and columns. The memory cells of each row are divided into a plurality of sections.

According to one embodiment of the present invention, the method comprises simultaneously writing a test bit to the plurality of memory cells in selected sections of the memory array in all memory banks, wherein the selected sections in different memory banks correspond to a same column address; individually and successively reading output bits from the memory cells in one of the selected sections of a designated row of a memory array in a designated bank corresponding to column address signals, row address signals, and bank selection signals; and error-checking the output bits with the test bit.

### BRIEF DESCRIPTION OF THE DRAWINGS

The invention will be described according to the appended drawings in which:

FIG. 1 shows a method illustrating a data compression test mode according to the prior art;

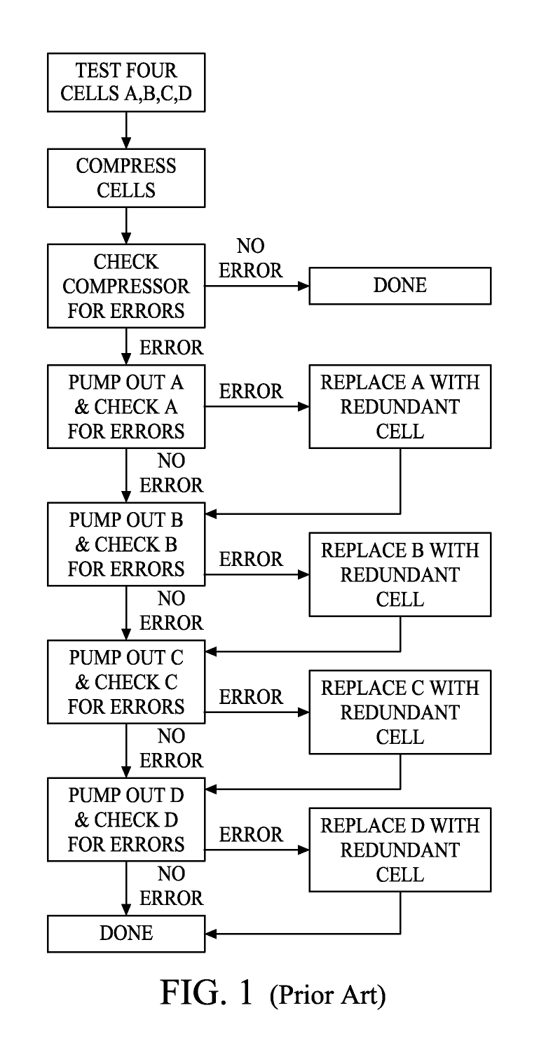

FIG. 2 shows a functional block diagram of a memory device according to one embodiment of the present invention;

FIG. 3 shows the detailed structure of a memory bank according to one embodiment of the present invention;

FIG. 4 shows the flow chart of a method for testing a memory array of a memory device according to one embodiment of the present invention;

FIG. 5 is a timing chart showing the operation of the memory device operating in a compression testing mode;

FIG. 6 shows the flow chart of a method for testing a memory device according to another embodiment of the present invention; and

FIG. 7 is a timing chart showing the operation of the memory device operating in a compression testing mode.

### DETAILED DESCRIPTION OF THE INVENTION

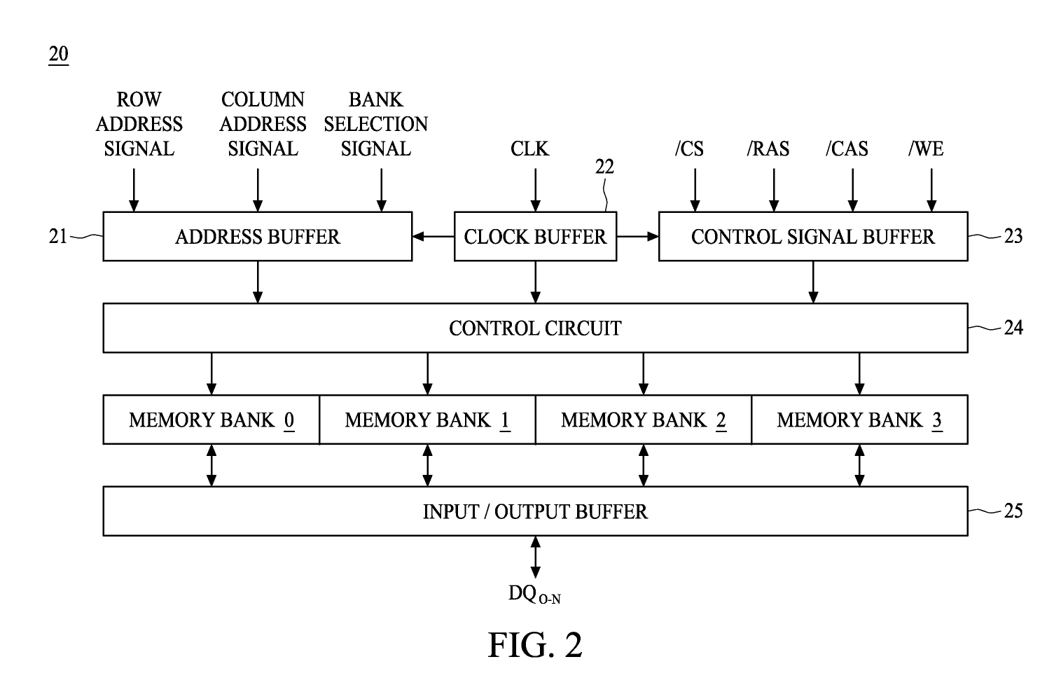

FIG. 2 shows a functional block diagram of a memory device 20 according to one embodiment of the present invention. Referring to FIG. 2, the memory device 20 comprises an address buffer 21, a clock buffer 22, a control signal buffer 23, a control circuit 24, four memory banks 0-3, and an input/output buffer 25. Each memory bank comprises a plurality of memory cells arranged into rows and columns, wherein the memory cells are accessed according to signals from the address buffer 21, the clock buffer 22, and the control signal buffer 23.

Referring to FIG. 2, the clock buffer 22 is configured to send an external clock signal CLK to the address buffer 21, the control signal buffer 23, and the control circuit 24. The control signal buffer 23 is configured to receive external control signals /CS, /RAS, /CAS, and /WE synchronously with the external clock signal CLK from the clock buffer 22 for sending control signals, i.e., active command ACT, pre-charge command PCH, write command WRITE, and read command READ, to the control circuit 24. The address buffer 21 is configured to receive external row address signals, column address signals, and bank selection signals synchronously with the external clock signal CLK from the clock buffer 22 for sending signals to the control circuit 24. One of the four memory banks 0-3 is selected according to the bank selection signal, and the memory cells are selected in the selected memory bank according to the row address and column address signals. The selected memory cells are activated and connected to the input/output buffer 25. The input/output buffer 25 is configured to send external data signals DQ_{0-N} to the selected memory cells in a write operation, or is configured to send read data signals of the selected memory cells to external circuits in a read operation.

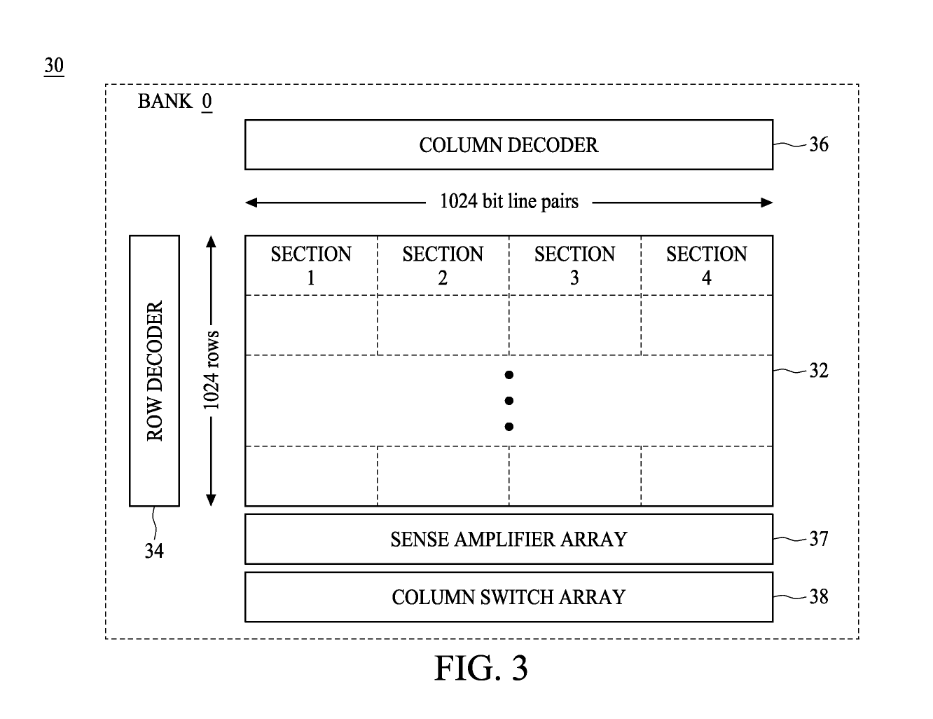

FIG. 3 shows the detailed structure of a memory bank 0 according to one embodiment of the present invention. Referring to FIG. 3, the memory bank 0 comprises a memory array 32, a row decoder 34, a column decoder 36, a sense amplifier array 37, and a column switch array 38. The remaining memory banks 1-3 are the same as the bank 0.

As shown in FIG. 3, the memory array 32 is made up of 1024 rows and 1024 bit line pairs, and the memory cells connected to the same row are divided into four sections. Each section holds 256 bits of data. The memory cells of each row are controlled by a conductive word line, which is controlled by the row decoder 34. The sense amplifier array 37 is made up of 1024 sense amplifiers for sensing and amplifying the data of the memory cells according to the selected row during an access. The column switch array 38 is made up of 1024 column switches and the column decoder 36 is configured to select four column switches out of 1024 column switches according to the external column address.

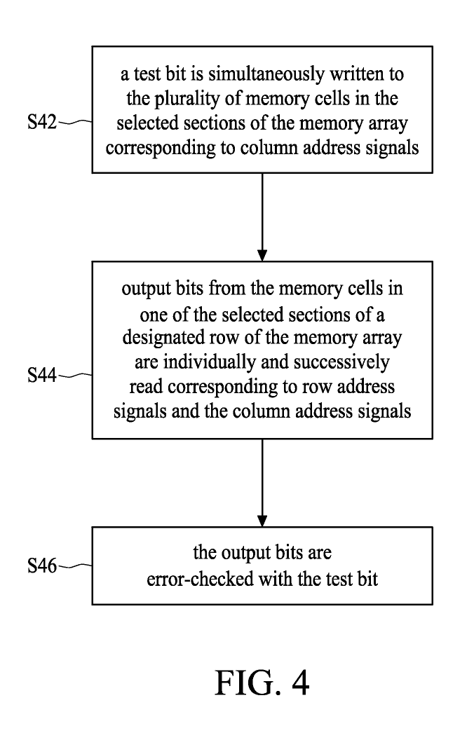

FIG. 4 shows the flow chart of a method for testing a memory array of a memory device according to one embodiment of the present invention, wherein the memory array comprises a plurality of memory cells arranged in rows and columns and the memory cells of each row are divided into a plurality of sections. In step S42, a test bit is simultaneously written to the plurality of memory cells in the selected sections of the memory array corresponding to column address signals. In step S44, output bits from the memory cells in one of the selected sections of a designated row of the memory array are individually and successively read corresponding to row address signals and the column address signals. In step S46, the output bits are error-checked with the test bit.

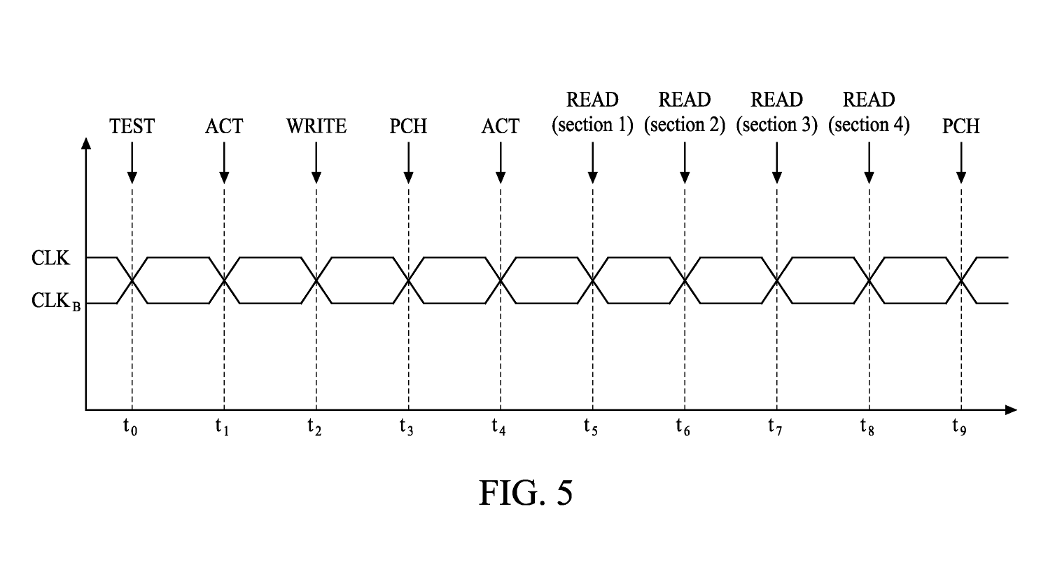

FIG. 5 is a timing chart showing the operation of the memory device operating in a compression testing mode. The details of the method for testing a memory array of a memory device are described in accordance with FIGS. 2, 3 and 5.

As shown in FIG. 5, at the rising edge of the clock signal CLK at time t₀, test command TEST is input to the memory array 32 in FIG. 3, which represents that the memory array 32 is entering a compression testing mode. Next, at time t₁, active command ACT and row address signals are input to the control circuit 24 in FIG. 2, and the row decoder 34 in FIG. 3 selects a word line out of 1024 word lines of the memory array 32. Next, at the rising edge of the clock signal CLK at time t₂, for writing the data sent from the external circuits to the memory cells, write command WRITE and column address signals are input to the control circuit 24 of the memory bank. In response to the write command WRITE and the compression testing mode, a test bit is simultaneously written to the memory cells in the selected sections of the memory cell array 32 corresponding to column address signals. In this embodiment, all sections of the memory array 32 are selected. Next, at time t₃, an operation of pre-charging the memory cells is carried out according to pre-charge command PCH.

At the rising edge of the clock signal CLK at time t₄, the active command ACT is input again and row address signals are sent to the control circuit 24 for selecting a word line out of 1024 word lines of the memory bank. In response to the selection of the word line, data from memory cells is transferred via 1024 bit line pairs to the sense amplifier array 37 for amplifying the data. At the rising edge of the clock signal at time t₅, for reading out the data held by the sense amplifier array 37, read command READ, row address signals, and column address signals are input to the control circuit 24 of the memory bank. In response to the read command READ, row address signals, and column address signals, output bits from the memory cells in different sections of a designated row are individually read. For example, as shown in FIG. 3, the bits stored in section 1 of a first row are read first and the bits stored in sections 2, 3, and 4 of the first row are read subsequently. At time t₉, the operation of pre-charging the memory cells is carried out again according to the pre-charge command PCH.

For detecting defective memory cells in the memory array, the output bits from a designated section of a designated row are error-checked with the test bit. If an error is found, such as an output bit that is not identical to the test bit, then a redundant memory cell is used to replace the defective cell. Since the output bits can be read individually according to the row and column address signals, the defective memory cell can be located more efficiently. In addition, when the output bits from different sections of the designated row are read, the row address does not change on the subsequent access, which permits elimination of the pre-charge time since the pre-charge time is incurred only when a different row is accessed on a subsequent transaction.

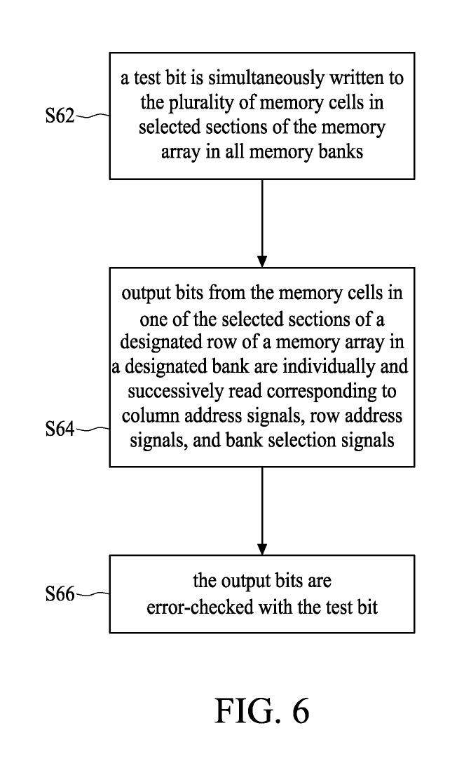

FIG. 6 shows the flow chart of a method for testing a memory device according to another embodiment of the present invention, wherein the memory device comprises a plurality of memory banks and each memory bank comprises a memory array having a plurality of memory cells arranged in rows and columns and the memory cells of each row are divided into a plurality of sections. In step S62, a test bit is simultaneously written to the plurality of memory cells in selected sections of the memory array in all memory banks, wherein the selected sections in different memory banks correspond to a same column address. In step S64, output bits from the memory cells in one of the selected sections of a designated row of a memory array in a designated bank are individually and successively read corresponding to column address signals, row address signals, and bank selection signals. In step S66, the output bits are error-checked with the test bit.

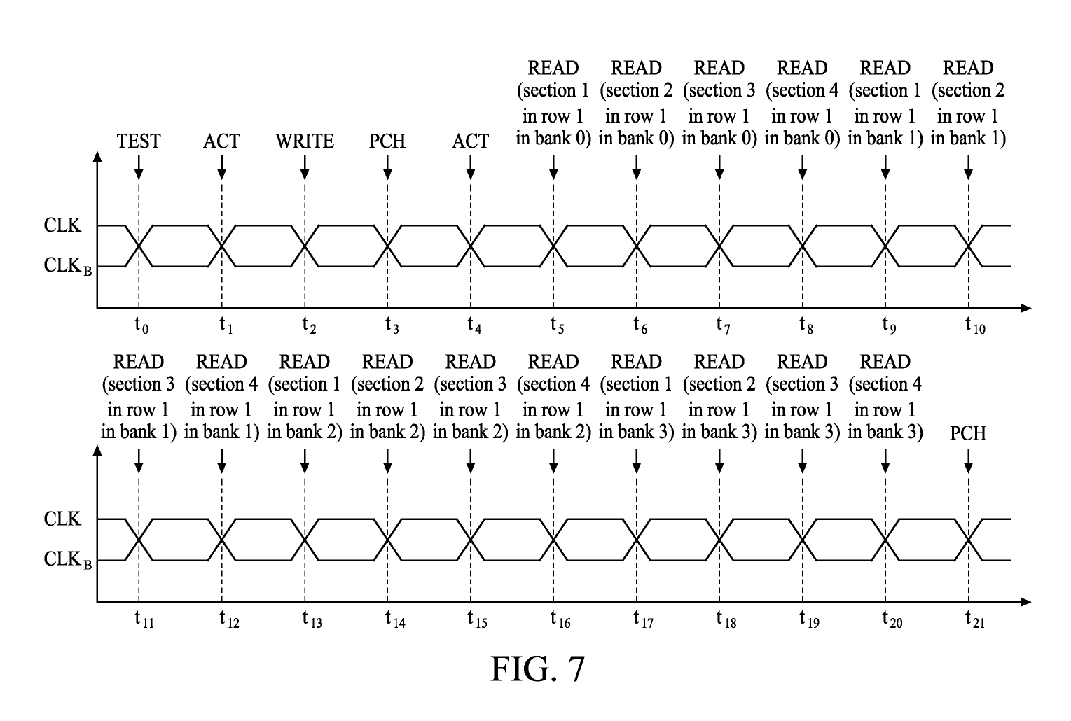

FIG. 7 is a timing chart showing the operation of the memory device operated in a compression testing mode. The details of the method for testing a memory array of a memory device are described in accordance with FIGS. 2-3 and FIG. 7.

As shown in FIG. 7, at the rising edge of the clock signal CLK at time to, test command TEST is input to the memory device 20 in FIG. 2, which represents that the memory device 20 enters in a compression testing mode. Next, at time t₁, active command ACT and row address signals are input to the control circuit 24 in FIG. 2. Next, at the rising edge of the clock signal CLK at time t₂, for writing the data sent from the external circuits to the memory cells, write command WRITE and column address signals are input to the control circuit 24 of the memory banks 0-3. In response to this write command WRITE and the compression testing mode, a test bit is simultaneously written to the memory cells in the selected sections of the memory cell array 32 of the memory banks 0-3. In this embodiment, all sections of the memory array 32 of all memory banks are selected. Next, at time t₃, an operation of pre-charging the memory cells is carried out according to pre-charge command PCH.

At the rising edge of the clock signal CLK at time t₄, the active command ACT and row address signals are input to the memory device 20. The row decoder 34 of the memory banks 0-3 selects a word line out of 1024 word lines of the memory array 32 in each bank. In response to the selection of the word line, data of memory cells is transferred via 1024 bit line pairs to the sense amplifier array 37 for amplifying the data. At the rising edge of clock signal at time t₅, for reading out the data held by the sense amplifier array 37, read command READ, column address signals, row address signals, and bank selection signals are input to the control circuit 24 of the memory banks 0-3. In response to this read command READ, column and row address signals, and bank selection signals, output bits from the memory cells in one of the selected sections of a designated row of a memory array 32 in a designated memory bank are individually and successively read. For example, as shown in FIG. 7, the bits stored in the section 1 in a first row in the memory bank 0 are read firstly and the bits stored in the sections 2, 3, and 4 in the first row in the memory bank 0 are read subsequently. Next, the bits stored in the sections 1, 2, 3, and 4 in the first row in the memory bank 1 are read successively corresponding to column address signals, row address signals, and bank selection signals. Next, the bits stored in the four sections in the first row in the memory banks 2-3 are read successively. At time t₂₁, the operation of pre-charging the memory cells is carried out again according to the pre-charge command PCH.

Similarly, for detecting defective memory cells in the memory array in different memory banks, the output bits from a designated section in a designated row in a selected memory bank are error-checked with the test bit. If an error is found, such as an output bit that is not identical to the test bit, then a redundant memory cell is used to replace the defective cell. Since the output bits can be read individually according to the row address signals, column address signals, and the bank selection signals, the defective memory cell can be located more efficiently. In addition, when the output bits from different sections of the designated row in the selected memory bank are read, the row address does not change on the subsequent access, and thus it is not necessary to execute the pre-charge operation.

The above-described embodiments of the present invention are intended to be illustrative only. Numerous alternative embodiments may be devised by those skilled in the art without departing from the scope of the following claims.

What is claimed is:

1. A method for testing a memory array of a memory device, the memory array comprising a plurality of memory cells arranged in rows and columns, the memory cells of each row being divided into a plurality of sections, and the method comprising:
simultaneously writing a test bit to the plurality of memory cells in the selected sections of the memory array corresponding to column address signals;
individually and successively reading output bits from the memory cells in one of the selected sections of a designated row of the memory array corresponding to the column address signals and row address signals; and
error-checking the output bits with the test bit.

2. The method of claim 1, further comprising pre-charging the plurality of memory cells after the writing step.

3. The method of claim 1, further comprising pre-charging the plurality of memory cells after the reading step.

4. A method for testing a memory device having a plurality of memory banks, each memory bank comprising a memory array having a plurality of memory cells arranged in rows and columns, the memory cells of each row being divided into a plurality of sections, and the method comprising:
simultaneously writing a test bit to the plurality of memory cells in selected sections of the memory array in all memory banks, wherein the selected sections in different memory banks correspond to a same column address;
individually and successively reading output bits from the memory cells in one of the selected sections of a designated row of a memory array in a designated bank corresponding to column address signals, row address signals, and bank selection signals; and
error-checking the output bits with the test bit.

5. The method of claim 4, further comprising pre-charging the plurality of memory cells after the writing step.

6. The method of claim 4, further comprising pre-charging the plurality of memory cells after the reading step.
